(19) United States
(12) Patent Application Publication
(10) Pub. No.: US 2004/0203194 A1
(43) Pub. Date: Oct. 14, 2004

(54) Method of resin-sealing a semiconductor device, resin-sealed semiconductor device, and forming die for resin-sealing the semiconductor device

(75) Inventor: Satoshi Hamasaki, Takahama-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/814,180

(22) Filed: Apr. 1, 2004

(30) Foreign Application Priority Data
Apr. 8, 2003 (JP) 2003-103862

(51) Int. Cl. H01L 21/44; H01L 21/48

(52) U.S. Cl. 438/127

(57) ABSTRACT

In a method of fabricating a resin-sealed semiconductor device, a semiconductor device is disposed inside a cavity of a mold and resin is injected through a gate of the mold into the cavity to seal the semiconductor device with the resin in a state where portions of lead portions are exposed. The gate is disposed only in a surface of the cavity facing the surface of the semiconductor chip. The resin is injected through the gate towards the surface of the semiconductor chip.

### CROSS REFERENCE TO RELATED APPLICATION

This application is based upon, claims the benefit of priority of, and incorporates by reference the contents of Japanese Patent Application No. 2003-103862 filed on Apr. 8, 2003.

### FIELD OF THE INVENTION

The present invention relates to a resin-sealed semiconductor device formed by sealing a semiconductor device with resin, a method of fabricating the resin-sealed semiconductor device, and a forming die that is applied to a resin-sealing process in the fabrication method.

### BACKGROUND OF THE INVENTION

Generally, a resin-sealed semiconductor device is formed by mounting a semiconductor chip on an island portion of a lead frame, connecting one side of the semiconductor chip to lead portions of the lead frame with plural bonding wires to create an integrated semiconductor device, and then sealing the semiconductor device with resin so that the semiconductor device is encapsulated.

Specifically, a resin-sealed semiconductor device can be fabricated by conducting a resin-sealing process (transfer mold) in which the semiconductor device is first disposed inside the cavity of a mold that is a forming die, injecting molten resin into the cavity through a gate to fill the cavity and curing the resin.

FIGS. 4A and 4B are block diagrams for describing the resin-sealing process in a related art resin-sealed semiconductor device. FIG. 4A is a schematic plan view, seen from above, of a state where a semiconductor device 100 is disposed in a lower mold 910. FIG. 4B is a schematic cross-sectional view along line IVB-IVB of FIG. 4A.

A mold 900 serving as a forming die is formed by aligning an upper mold 920 and a lower mold 910. The mold 900 includes a cavity 940 connected to the end of a runner 970 that extends from a cull 960 serving as a resin reservoir.

The semiconductor device 100 is disposed inside the cavity 940 of the mold 900. The semiconductor device 100 is formed by the surface of a semiconductor chip 10 mounted on one side of an island portion 20 of a lead frame being connected to lead portions 30 of the lead frame positioned around the semiconductor chip 10 via plural bonding wires 40 comprising gold wires.

As shown in FIG. 4B, molten resin 60 inside a resin pot 950 is extruded towards the cull 960 by a plunger, flows through the runner 970 and is injected through a gate 980 into the cavity 940. Thus, the cavity 940 is filled with the resin 60. The runner 970 may be formed along the surfaces of the lead portions 30 of the lead frame, and the resin 60 flows along the lead portions 30 positioned in the runner 970 and is injected through the gate 980 into the cavity 940.

The resin 60 that has been injected into the cavity 940 then flows along the surface (i.e., bonding surface) of the semiconductor chip 10. When this happens, the resin 60 flows along the arranging direction of the wires 40 as shown by the arrows in FIG. 4A. As a result, the wires 40 contacting the resin 60 are pushed by the resin 60 and flow in the direction of adjacent wires 40. For this reason, the wires 40 contact each other and a short circuit occurs.

In particular, in a semiconductor device where the pitch of the intervals between the wires 40 has been narrowed, as shown in FIG. 5A, or a semiconductor device where the arrangement of the wires 40 is irregular, as shown in FIG. 5B, relatively long wires 40 are present. Therefore, the tendency for the intervals between the wires 40 to become narrow is significant and it becomes easy for a short circuit resulting from the wires 40 contacting each other to occur.

In order to suppress this problem, methods have been proposed where plural gates and runners extending from the resin pot are disposed to reduce pressure loss of the melted flowing resin and improve filling efficiency, whereby deformation of the bonding wires is suppressed (e.g., see JP-A Nos. 2-297946 and 2000-58573).

For example, as shown in FIGS. 6A, 6B and 6C, by using a mold disposed with two gates 980 with respect to one cavity 940, it becomes possible to reduce, by about ½, the flow speed of the resin 60 flowing through the cavity 940 without changing the filling amount with respect to a single gate type mold. Therefore, wire flow can be made smaller and the resulting deformation of wire and short-circuit failure between wires can be reduced.

However, with this plural gate type mold, the resin 60 is filled in the order indicated by the dotted lines in FIGS. 6A, 6B and 6C, and it becomes easy for a void B to arise due to air intake at the confluence of the resin 60 streams.

When such a void B is present in the resin 60 in the finished resin-sealed semiconductor device, it becomes easy for cracks in the resin 60 to arise at the portion of the void B, which adversely affects the reliability of the device.

Also, as described in connection with FIGS. 4A and 4B, the runner 970 is formed along the surfaces of the lead portions 30 of the lead frame, and the resin 60 flows along the lead portions 30 positioned in the runner 970 and is injected through the gate 980 into the cavity 940.

For this reason, as shown in FIG. 4B, it is easy for resin burs to remain at sites K1 and K2 positioned in the vicinity of the gate 980 and the runner 970 of the lead portions 30 after the mold 900 has been removed. It is easy for such resin burs to attract dust and foreign matter and thereby lead to breaking of the lead portions 30 or become a problem in later processes such as the formation process.

### SUMMARY OF THE INVENTION

In view of the above-described problems, it is an object of the present invention to achieve an appropriate balance between the prevention of voids in resin and the prevention of short circuits between bonding wires in a resin-sealed semiconductor device.

In order to achieve this object, a first aspect of the invention provides a method of fabricating a resin-sealed semiconductor device in which a semiconductor device formed by disposing the undersurface of a semiconductor chip on one side of an island portion of a lead frame and connecting the surface of the semiconductor chip to lead portions of the lead frame disposed around the semiconductor chip with plural bonding wires, is disposed inside a cavity of a forming die and resin is injected through a gate of the forming die into the cavity to seal the semiconductor device with the resin in a state where portions of the lead portions are exposed. The gate of the forming die is disposed only in a surface of the cavity facing the surface of the semiconductor chip. The resin is injected through the gate towards the surface of the semiconductor chip.

According to the first aspect of the invention, it becomes possible to inject the resin into the cavity from above the surface (i.e., bonding surface) of the semiconductor chip, thereby causing the resin to flow and fill the cavity with the resin.

By doing this, the wires can be prevented from flowing in the direction of adjacent wires because the resin flows in a direction substantially orthogonal to the arranging direction of the plural bonding wires present on the surface of the semiconductor chip. For this reason, short circuits resulting from wire flow can be prevented even if resin molding is conducted without using a forming die having plural gates in which voids are easily generated.

Also, in the forming die of the present invention, because the gate is disposed in the surface facing the surface of the semiconductor chip, a runner connecting the gates is not positioned along the surfaces of the lead portions of the lead frame. For this reason, it becomes difficult for resin burs adhering to the lead portions to arise.

Thus, according to this invention, an appropriate balance between the prevention of voids in resin and the prevention of short circuits between bonding wires in a resin-sealed semiconductor device can be achieved.

A second aspect of the invention provides the method of fabricating a resin-sealed semiconductor device of the first aspect, wherein a semiconductor device where a support board for preventing the island portion from being bent by the pressure of the resin in the injection direction of the resin when the resin is injected is disposed at the other side of the island portion is used as the semiconductor device.

When the island portion is pressed and bent by the pressure of the resin in the injection direction of the resin when the resin is injected and made to flow from above the surface of the semiconductor chip, the positional relationship between the semiconductor chip and the lead portions changes in accompaniment with the bending, and the bonding wires connecting the semiconductor chip to the lead portions become deformed.

With respect to this, according to the present invention, bending of the island portion is suppressed by the support board disposed at the other side of the island portion. Thus, deformation of the wires accompanying the bending can be prevented, and, as a result, breaking of the wires can be prevented, which is preferable.

A third aspect of the invention provides a forming die that is applied to a process where a semiconductor device, which is formed by disposing the undersurface of a semiconductor chip on one side of an island portion of a lead frame and connecting the surface of the semiconductor chip to lead portions of the lead frame disposed around the semiconductor chip with plural bonding wires, is sealed with resin so as to encapsulate the semiconductor device, with the forming die including a cavity in which the semiconductor device is disposed and a gate for injecting the resin into the cavity, wherein the gate is disposed only in a surface of the cavity facing the surface of the semiconductor chip and the resin is injected through the gate towards the surface of the semiconductor chip.

According to this invention, a forming die that can be appropriately used in the fabrication methods of the first and second aspects can be provided.

A fourth aspect of the invention provides a resin-sealed semiconductor device where a semiconductor device, which is formed by disposing the undersurface of a semiconductor chip on one side of an island portion of a lead frame and connecting the surface of the semiconductor chip to lead portions of the lead frame disposed around the semiconductor chip with plural bonding wires, is sealed with resin in a state where portions of the lead portions are exposed, wherein an injection mark of the resin is positioned at an end surface of the resin facing the surface of the semiconductor chip.

This invention can be appropriately fabricated by the fabrication method of the first aspect, and the effects thereof are the same as those of the invention of the first aspect.

A fifth aspect of the invention provides the resin-sealed semiconductor device of the fourth aspect, wherein a support board that supports the island portion is disposed at the other side of the island portion.

This invention can be appropriately fabricated by the fabrication method of the second aspect, and the effects thereof are the same as those of the invention of the second aspect.

### BRIEF DESCRIPTION OF THE DRAWINGS

The above and other objects, features and advantages of the present invention will become more apparent from the following detailed description made with reference to the accompanying drawings. In the drawings:

FIGS. 1A and 1B are block diagrams of a resin-sealed semiconductor device pertaining to an embodiment of the invention, with FIG. 1A being a schematic cross-sectional view and FIG. 1B being a schematic plan view;

FIGS. 2A and 2B are block diagrams of a mold used in a method of fabricating the resin-sealed semiconductor device, with FIG. 2A being a schematic cross-sectional view of the mold and FIG. 2B being a schematic plan view of a lower mold of the mold;

FIGS. 3A and 3B are block diagrams of the mold used in the method of fabricating the resin-sealed semiconductor device, with FIG. 3A being a schematic plan view of a middle mold of the mold and FIG. 3B being a schematic plan view of an upper mold of the mold;

FIGS. 4A and 4B are block diagrams for describing a related art resin-sealing process, with FIG. 4A being a schematic plan view, seen from above, of a state where a semiconductor device is disposed in a lower mold and FIG. 4B being a schematic cross-sectional view along line IVB-IVB of FIG. 4A;

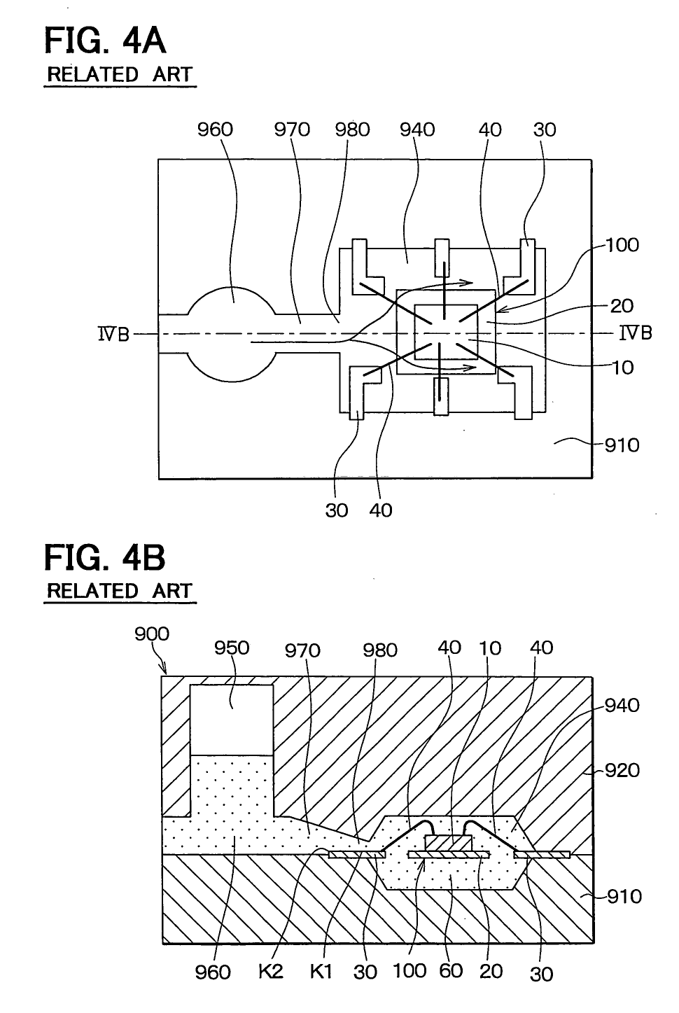

FIG. 5A is a plan view showing a semiconductor device where the pitch of intervals between bonding wires has been narrowed, and FIG. 5B is a plan view showing a semiconductor device where the arrangement of bonding wires is irregular; and

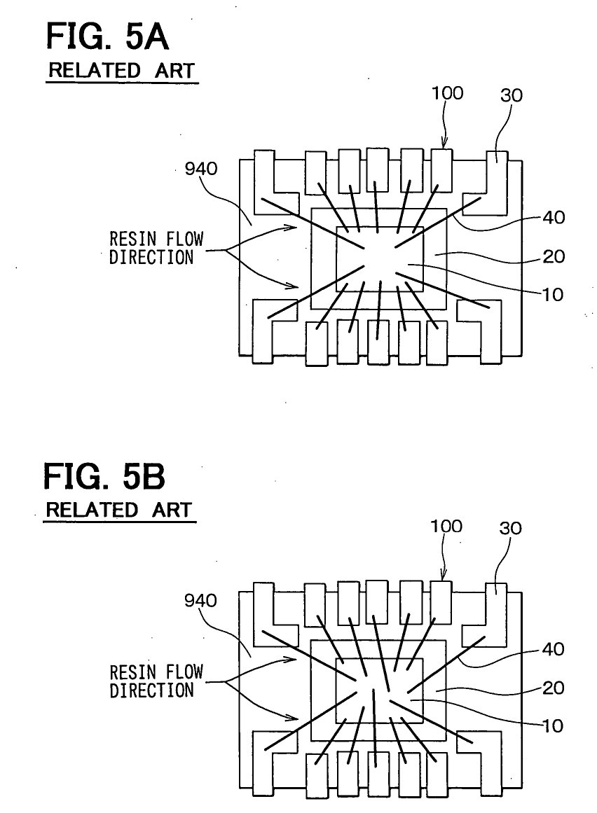

FIGS. 6A, 6B and 6C are explanatory diagrams schematically showing the flow of resin in a related art plural gate type mold.

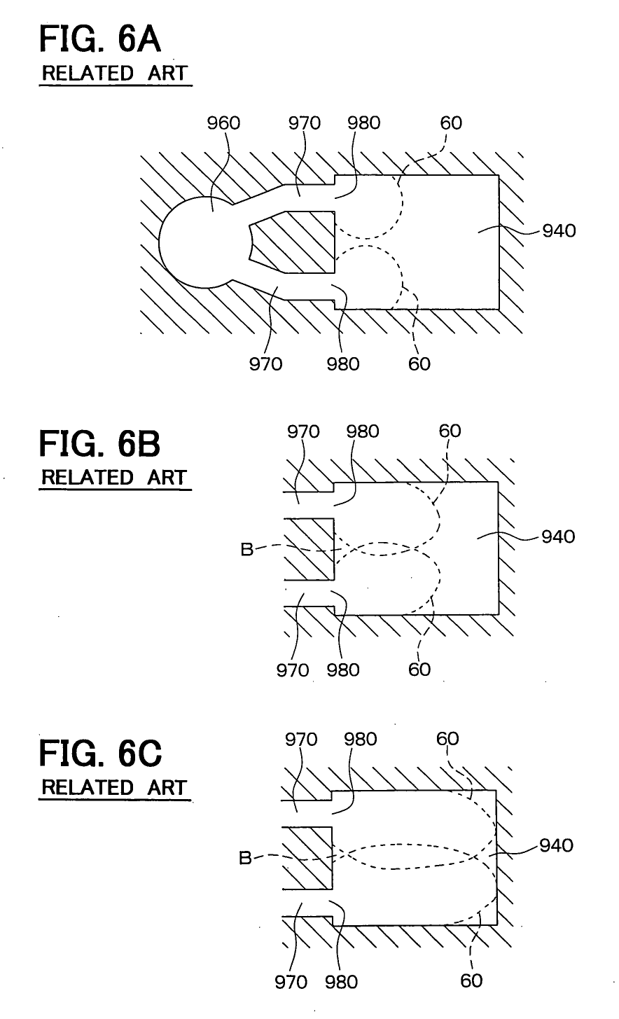

### DESCRIPTION OF THE PREFERRED EMBODIMENT

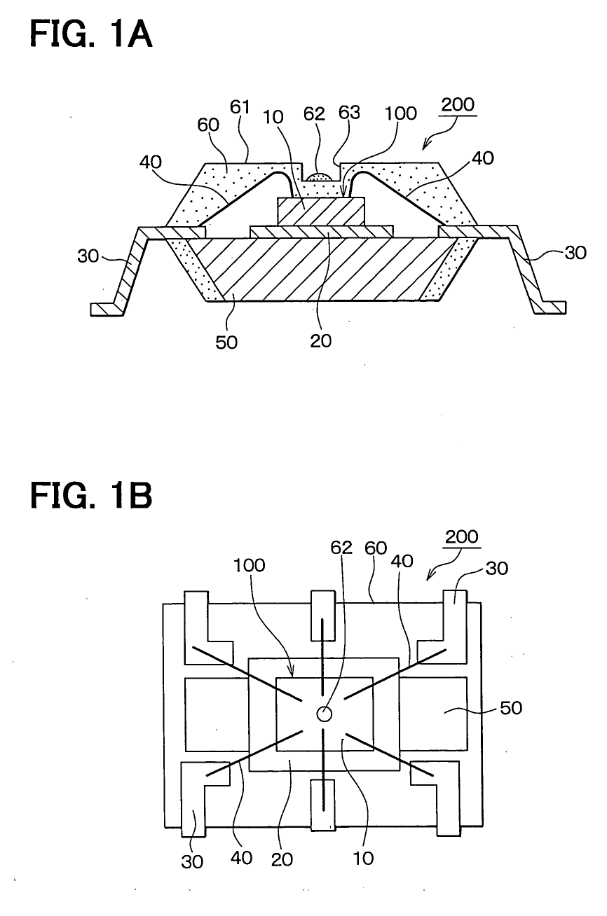

The present invention will be described below on the basis of an embodiment shown in the drawings. FIGS. 1A and 1B are block diagrams of a resin-sealed semiconductor device 200 pertaining to a preferred embodiment of the invention. FIG. 1A is a schematic cross-sectional view of the resin-sealed semiconductor device 200, and FIG. 1B is a schematic plan view of the resin-sealed semiconductor device 200 as seen from above. It should be noted that FIG. 1B is a view seen through resin 60.

In this resin-sealed semiconductor device 200, component parts excluding the resin 60 are configured as a semiconductor device 100. In the semiconductor device 100, an undersurface side of a semiconductor chip 10 is mounted on one side of an island portion 20 of a lead frame. The semiconductor device 100 may be a resin-sealed semiconductor device in which a semiconductor chip is mounted on a lead frame and the semiconductor chip and the lead frame are connected by bonding wires, such as a Quad Flat Package (QFP) or a Small Outline Package (SOP).

An ordinary IC chip comprising elements such as transistors formed on a silicon chip can be used for the semiconductor chip 10. Here, the undersurface of the semiconductor chip 10 is adhered to one side of the island portion 20 via an adhesive such as a die paste.

Lead portions 30 of a lead frame are disposed around the periphery of the semiconductor chip 10 and the island portion 20. Here, the lead portions 30 are plurally disposed around the periphery of end surface sides of the tabular semiconductor chip 10. A common lead frame, such as a lead frame where the island portion 20 and the lead portions 30 are formed by punching and etching a plate material comprising copper, a copper alloy or an alloy including nickel, can be used as the lead frame.

The surface of the semiconductor chip 10 and the lead portions 30 disposed around the periphery of the semiconductor chip 10 are connected by plural bonding wires 40. Common bonding wires, such as bonding wires formed by wire-bonding a wire material comprising gold or aluminum, can be used as the bonding wires 40.

A heat sink 50 is disposed at the other side of the island portion 20 of the lead frame. The heat sink 50 is a plate material comprising a material having excellent heat conductivity, such as copper or molybdenum, and the heat sink 50 and the island portion 20 are integrally fixed by caulking or adhering them together.

Although the heat sink 50 preferably does not constitute a portion of the semiconductor device 100, the semiconductor device 100 of the present embodiment is preferably disposed with the heat sink 50. Due to the heat sink 50, heat generated by the semiconductor chip 10 is dissipated. Also, the heat sink 50 is configured as a support board supporting the island portion 20.

The semiconductor device 100 is sealed, so as to be encapsulated, with the resin 60 in a state where portions of the lead portions 30 are exposed. Here, portions of the lead portions 30 positioned inside the resin 60 are inner leads, and portions of the lead portions 30 positioned outside the resin 60 are outer leads.

It should be noted that in the present embodiment the undersurface of the heat sink 50 is exposed through the resin 60 in order to further improve heat dissipation. However, the heat sink 50 does not invariably have to be exposed through the resin 60 and may also be covered by the resin 60.

A common sealing resin can be used as the resin 60. Examples of the resin 60 used include an epoxy resin including a cresol-novolac skeleton and an epoxy resin including a biphenyl skeleton.

The resin-sealed semiconductor device 200 is fabricated by disposing the semiconductor device 100 inside a cavity in a forming die and injecting resin into the cavity through a gate in the forming die to thereby seal the semiconductor device 100 with the resin.

As shown in FIGS. 1A and 1B, an injection mark 62 of the resin 60 is present at an end surface 61 of the resin 60 facing the semiconductor chip 10 (i.e., facing a bonding surface of the semiconductor chip 10).

The injection mark 62 is formed at a position corresponding to the gate in the forming die. The injection mark 62 is a mark that remains as a bur when the resin-sealed semiconductor device 200 is removed from the forming die after the semiconductor device 100 has been sealed with the resin 60.

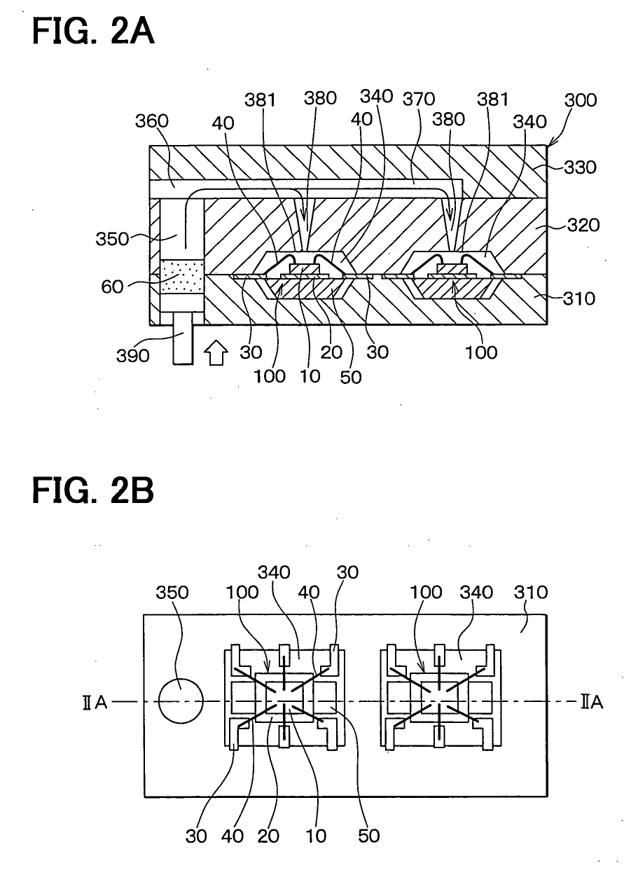

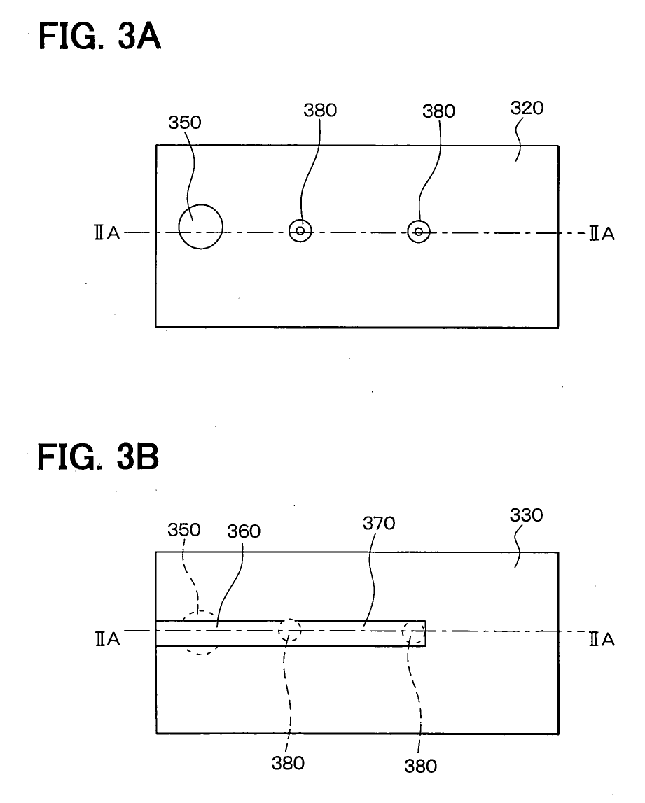

Next, a method of fabricating the resin-sealed semiconductor device 200 will be specifically described with reference to FIGS. 2A, 2B, 3A and 3B.

FIGS. 2A, 2B, 3A and 3B are diagrams showing the configuration of a mold 300 serving as a forming die used in the method of fabricating the resin-sealed semiconductor device 200. The mold 300 includes a lower mold 310, a middle mold 320 and an upper mold 330 stacked and aligned.

FIG. 2A is a schematic cross-sectional view of the mold 300, and FIG. 2B is a schematic plan view of the lower mold 310 of the mold 300. FIG. 2B shows a state where the semiconductor devices 100 have been disposed in the lower mold 310. FIG. 3A is a schematic plan view of the middle mold 320, and FIG. 3B is a schematic plan view of the upper mold 330.

The cross section shown in FIG. 2A corresponds to a cross section along line IIA-IIA of FIGS. 2B, 3A and 3B. In order to show the positional relationship among component elements, a resin pot 350 and gates 380 not formed in the upper mold 330 are indicated by dotted lines in FIG. 3B for convenience.

First, the configuration of the mold 300 will be described with reference to FIGS. 2A, 2B, 3A and 3B. Each of the lower mold 310, the middle mold 320 and the upper mold 330 of the mold 300 is formed by cutting so that the three molds 310, 320 and 330 can be aligned.

Cavities 340 are formed by recessed portions formed in the lower mold 310 and the middle mold 320. Two cavities 340 are shown here, but in actuality more cavities 340 are formed because numerous semiconductor devices 100 formed by multiple lead frames are resin-sealed at one time.

Similar to a common transfer mold, the resin 60, which has been injected from a resin pot 350 and softened, is pressurized, sent to a cull 360, passes through a runner 370, and is injected through the gates 380 into the cavities 340.

In the mold 300 of the present embodiment, one gate 380 is disposed with respect to one cavity 340. The gates 380 are disposed in surfaces 381 of the cavities 340 facing the surfaces (bonding surfaces) of the semiconductors chip 10, and the resin 60 is injected through the gates 380 towards the surfaces of the semiconductor chips 10.

Specifically, in the present embodiment, the gates 380 are configured as conical holes that penetrate the middle mold 320, from the runner 370 side to the cavity 340 side, and narrow towards the cavity 340 side. The runner 370 is formed in the upper mold 330 so as to connect the gates 380.

The resin-sealed semiconductor device 200 of the present embodiment is fabricated by the following procedure using the mold 300.

First, the lead frame is prepared. Although it is not shown, the lead frame is one where the island portion 20 and the lead portions 30 are integrally connected by a frame portion of the lead frame or tie bars. Then, the heat sink 50 is fixed to the island portion 20 of the lead frame by caulking or adhering them together.

Next, the undersurface side of the semiconductor chip 10 is mounted on the island portion 20 of the lead frame, and the surface of the semiconductor chip 10 is connected by the bonding wires 40 to the lead portions 30 of the lead frame by conducting wire bonding. Thus, the semiconductor device 100 is formed.

Next, as shown in FIG. 2B, the semiconductor device 100 is disposed in the lower mold 310. Then, as shown in FIG. 2A, the lower mold 310, the middle 320 and the upper mold 330 are aligned and closed. In this manner, the semiconductor device 100 is disposed inside the cavity 340 of the mold 300.

Then, as shown in FIG. 2A, the resin-sealing process is conducted. By disposing a heater around the outer periphery of the mold 300, the mold 300 is heated to a temperature equal to or greater than the melting temperature of the resin 60.

Next, the molten resin 60 is pressurized by a plunger 390 from the resin pot 350 to send the resin 60 to the cull 360. From there, the resin 60 is injected into the cavities 340 via the runner 370 and the gates 380. Thus, the resin 60 is injected into the cavities 340 from above the bonding surfaces of the semiconductor chips 10 and flows to fill the cavities 340.

Then, after the filling of the cavities 340 with the resin 60 ends and the resin 60 has been cured, the semiconductor devices 100 are removed from the mold 300. Immediately after the curing of the resin 60, the resin 60 filling the inside of the gates 380 and the resin 60 filling the inside of the cavities 340 are integrally connected, but the resin 60 breaks at the boundaries between the gates 380 and the cavities 340 when the mold 300 is removed.

Thus, the injection mark 62 shown in FIGS. 1A and 1B is formed in the resin 60. Thereafter, the resin-sealed semiconductor device 200 shown in FIGS. 1A and 1B is finished by conducting processes such as separating the frame portion of the lead frame and the tie bars and forming.

In the present embodiment, a mold where the gates 380 are disposed in the surfaces 381 of the cavities 340 facing the surfaces of the semiconductor chips 10 and the resin 60 is injected through the gates 380 towards the surfaces of the semiconductor chips 10 is used as the mold 300.

Thus, as described above, it becomes possible to inject the resin 60 into the cavities 340 from above the surfaces (i.e., the bonding surfaces) of the semiconductor chips 10, causing the resin 60 to flow and fill the cavities 340 with the resin 60.

By doing this, the wires 40 can be prevented from flowing in the direction of adjacent wires 40 because the flowing resin 60 flows in a direction substantially orthogonal to the arranging direction of the plural bonding wires 40 present on the surfaces of the semiconductor chips 10. For this reason, short circuits resulting from wire flow can be prevented even if resin molding is conducted without using a forming die having plural gates in which voids are easily generated.

Also, in the mold 300 of the present embodiment, because the gates 380 are disposed in the surface facing the surfaces of the semiconductor chips 10, the runner 370 connecting the gates 380 is not positioned along the surfaces of the lead portions 30 of the lead frame as in the related art. For this reason, it becomes difficult for resin burs adhering to the lead portions 30 to arise.

Also, although the injection mark 62 of the resin 60 is present at the end surface 61 of the resin 60 facing the surface of the semiconductor chip 10, a recessed portion 63 is disposed in the end surface 61 as shown in FIG. 1A and the top of the injection mark 62 is made lower than the end surface 61, whereby it does not significantly affect later processes even if the injection mark 62 is present at such a position.

Thus, according to the present embodiment, it is possible to appropriately achieve a balance between the prevention of voids in the resin 60 and the prevention of short circuits between the bonding wires 40 in the resin-sealed semiconductor device 200.

Also, in the present embodiment, the semiconductor device 100 preferably includes the heat sink 50, which serves as a support board supporting the island portion 20, disposed at the other side of the island portion 20 of the lead frame.

Generally, because the lead frame has a thin tabular shape, there is the potential for the island portion 20 to be pressed and bent by the pressure of the resin 60 in the injection direction of the resin 60 when the resin 60 is injected and made to flow from above the surface of the semiconductor chip 10. When the island portion 20 bends in this manner, the positional relationship between the semiconductor chip 10 and the lead portions 30 changes along with the bending, and the bonding wires 40 connecting the semiconductor chip 10 to the lead portions 30 become deformed.

With respect to this, the heat sink 50 serving as the support board 50 is disposed at the other side of the island portion 20 so that bending of the island portion 20 is suppressed by the heat sink 50. Thus, deformation of the wires 40 accompanying the bending can be prevented and, as a result, breaking of the wires 40 can be prevented, which is preferable.

It should be noted that, other than the heat sink 50, a material such as a metal that is more rigid than the island portion 20 of the lead frame may be used as the support board. Also, a semiconductor device not disposed with the support board may be used as the case may be.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A method of resin-sealing a semiconductor device formed by disposing the undersurface of a semiconductor chip on one side of an island portion of a lead frame and connecting the surface of the semiconductor chip to lead portions of the lead frame disposed around the semiconductor chip with plural bonding wires, the method comprising:
disposing the semiconductor chip inside a cavity of a forming die and injecting resin through a gate of the forming die into the cavity to seal the semiconductor device with the resin in a state where portions of the lead portions are exposed,
wherein the gate of the a forming die is disposed only in a surface of the cavity facing the surface of the semiconductor chip and the resin is injected through the gate towards the surface of the semiconductor chip.

2. The method of claim 1, wherein the semiconductor device includes a support board at the other side of the island portion, wherein the support board substantially prevents the island portion from being bent by pressure of the resin in the injection direction of the resin during the injecting.

3. The method of claim 1, wherein the resin is injected through the gate towards the surface of the semiconductor chip in a direction that is substantially orthogonal to the surface of the semiconductor chip.

4. A forming die for resin-sealing a semiconductor device with a resin so as to encapsulate the semiconductor device, wherein the semiconductor device is formed by disposing the undersurface of a semiconductor chip on one side of an island portion of a lead frame and connecting the surface of the semiconductor chip to lead portions of the lead frame disposed around the semiconductor chip with plural bonding wires, the forming die comprising:
a cavity in which the semiconductor device is disposed; and
a gate for injecting the resin into the cavity, wherein the gate is disposed only in a surface of the cavity to face the surface of the semiconductor chip and so that the resin is injected through the gate towards the surface of the semiconductor chip.

5. The forming die of claim 4, wherein the gate is disposed so that the resin is injected through the gate towards the surface of the semiconductor chip in a direction that is substantially orthogonal to the surface of the semiconductor chip.

6. A resin-sealed semiconductor device in which a semiconductor device formed by disposing an undersurface of a semiconductor chip on one side of an island portion of a lead frame and connecting the surface of the semiconductor chip to lead portions of the lead frame disposed around the semiconductor chip with plural bonding wires, is sealed with resin in a state where portions of the lead portions are exposed, the resin-sealed semiconductor device comprising:
an injection mark of the resin positioned at an end surface of the resin facing the surface of the semiconductor chip.

7. The resin-sealed semiconductor device of claim 6, further comprising a support board for supporting the island portion disposed at the other side of the island portion.

8. The resin-sealed semiconductor device of claim 6, further comprising a recessed portion disposed in the end surface of the resin, wherein the top of the injection mark is made lower than the end surface.
